(19) United States
(12) Patent Application Publication
(10) Pub. No.: US 2011/0241080 A1
(43) Pub. Date: Oct. 6, 2011

(54) SOLID-STATE IMAGING DEVICE, METHOD FOR MANUFACTURING THE SAME, AND ELECTRONIC APPARATUS

(75) Inventor: Shinya Yamakawa, Kanagawa (JP)

(73) Assignee: SONY CORPORATION, Tokyo (JP)

(21) Appl. No.: 13/070,624

(22) Filed: Mar. 24, 2011

(30) Foreign Application Priority Data
Mar. 31, 2010 (JP) 2010-080526

(51) Int. Cl. H01L 27/148; H01L 31/18

(52) U.S. Cl. 257/225; 438/75; 257/E27.151; 257/E31.084

(57) ABSTRACT

Disclosed herein is a solid-state imaging device, including a plurality of unit pixels, wherein the plurality of unit pixels include: a photoelectric conversion element; a first transfer gate; a charge retaining region; a second transfer gate; and a floating diffusion region; a boundary part between the photoelectric conversion element and the charge retaining region having a structure of an overflow path formed at a potential determining a predetermined amount of charge, the overflow path transferring a charge by which the predetermined amount of charge is exceeded as a signal charge from the photoelectric conversion element to the charge retaining region, and the first transfer gate having two electrodes with different work functions as gate electrodes arranged above the overflow path and above the charge retaining region, respectively.

### BACKGROUND OF THE INVENTION

1. Field of the Invention

The present invention relates to a solid-state imaging device, a method for manufacturing the same, and an electronic apparatus, and particularly to a solid-state imaging device, a method for manufacturing the same, and an electronic apparatus in which an overflow barrier can be formed stably.

2. Description of the Related Art

Solid-state imaging devices include for example a CMOS (Complementary Metal Oxide Semiconductor) image sensor that reads out a light charge accumulated in a pn-junction capacitance of a photodiode as a photoelectric conversion element via a MOS transistor.

The CMOS image sensor performs an operation of reading out the light charge accumulated in the photodiode in each pixel, each row or the like. Thus, exposure periods for accumulating the light charge in all pixels cannot be made to coincide with each other, and distortion occurs in an image photographed when a subject is moving, for example.

FIG. 1 shows an example of constitution of a unit pixel.

As shown in FIG. 1, the unit pixel 20A includes in addition to a photodiode (PD) 21 a transfer gate 24, a floating diffusion region (FD) 25, a reset transistor 26, an amplifying transistor 27, and a selecting transistor 28.

In the unit pixel 20A, the photodiode 21 is for example a buried type photodiode formed by burying an N-type buried layer 34 with a P-type layer 33 formed in a surface in a P-type well layer 32 formed on an N-type substrate 31. The P-type well layer 32 is formed under the second transfer gate 24. When the second transfer gate 24 is in an off state, the movement of charge is obstructed by a potential barrier. When the second transfer gate 24 is in an on state, on the other hand, the potential barrier under the second transfer gate 24 is lowered, the charge accumulated by the pn junction of the photodiode 21 is transferred to the floating diffusion region 25, and a variation in voltage of the floating diffusion region 25 is output to a signal line 17 via the amplifying transistor 27.

The CMOS image sensor having such a unit pixel has a problem of distortion occurring when photographing a moving subject, as described above.

### (Mechanical Shutter System)

A mechanical shutter system using a mechanical light shielding portion is in wide use as one of methods for achieving global exposure for performing image pickup in a same exposure period in all pixels in the solid-state imaging device having the unit pixel 20A of the above-described constitution. The global exposure is performed by starting exposure on an all-pixel simultaneous basis and ending the exposure on an all-pixel simultaneous basis.

This mechanical shutter system makes periods in which light is incident on the photodiode 21 and a light charge is generated in all the pixels coincide with each other by mechanically controlling the exposure period. The mechanical shutter system reads out signals sequentially after a state is obtained in which a mechanical shutter is closed and thus essentially no light charge is accumulated. However, because the mechanical shutter system needs a mechanical light shielding portion, miniaturization is difficult, and because there is a limit to a mechanical driving speed, the simultaneity of the mechanical shutter system is inferior to that of an electrical method.

### (Pixel Structure Having Memory Part)

FIG. 2 shows an example of constitution of a unit pixel of a CMOS image sensor including a memory part (MEM).

As shown in FIG. 2, the unit pixel 20B includes a charge retaining region (hereinafter referred to as a “memory part (MEM)”) 23 separately from a floating diffusion region (FD) 25. The memory part 23 temporarily retains a light charge accumulated by a buried type photodiode (PD) 21. The unit pixel 20B further includes a first transfer gate 22 for transferring the light charge accumulated by the photodiode (PD) 21 to the memory part 23.

In the unit pixel 20B having the memory part 23, the light charge accumulated by the photodiode (PD) 21 is once transferred to the memory part 23, the light charge is thereafter sequentially transferred to the floating diffusion region 25, and a readout operation is performed. However, because the first transfer gate 22 and the memory part 23 are formed within the same pixel, a maximum amount of charge that can be accumulated in the photodiode (PD) 21 is reduced. Such a CMOS image sensor is disclosed in Japanese Patent Laid-Open No. 2006-311515 as Patent Document 1 and Japanese Patent Laid-Open No. Hei 11-177076 as Patent Document 2, for example.

(Pixel Structure in which Photodiode and Memory Part are Integrated with Each Other by Overflow Path)

The present applicant has previously proposed a pixel structure in which a photodiode 21 and a memory part 23 are connected to each other in a depleted state while a potential barrier (generally referred to as an overflow barrier) is formed in a charge transfer path between the photodiode 21 and the memory part 23, as a method for solving the problem of the system using the memory part 23 described above, see Japanese Patent Laid-Open No. 2009-268083 (FIG. 19 and FIG. 21), as Patent Document 3, for example.

FIG. 3 shows an example of constitution of a unit pixel proposed in Patent Document 3. As shown in FIG. 3, the unit pixel 20C has a structure in which an overflow path 30 is formed by providing an N-impurity diffused region 37 under a gate electrode 22A and in a boundary part between a photodiode 21 and a memory part 23.

The potential of the impurity diffused region 37 needs to be low in order to form the overflow path 30. The N-impurity diffused region 37 can be formed by lightly doping the impurity diffused region 37 with an N-type impurity.

FIG. 4 is a diagram of potential in an X-direction of the unit pixel 20C in FIG. 3 (A-A′ in FIG. 3). As is clear from the X-direction potential diagram of FIG. 4, the potential of the boundary part between the photodiode 21 and the memory part 23 is lowered by providing the N-impurity diffused region 37 in the boundary part. The part whose potential is lowered becomes the overflow path 30. A charge that is generated in the photodiode 21 and by which the potential of the overflow path 30 is exceeded automatically leaks into the memory part 23 and is accumulated in the memory part 23. A generated charge not exceeding the potential of the overflow path 30 is accumulated in the photodiode 21.

Thus, the height of the potential of the overflow barrier is controlled by impurity concentration, and the overflow path 30 functions as an intermediate charge transfer part. Specifically, the overflow path 30 as an intermediate charge transfer part transfers a charge that is generated by photoelectric conversion in the photodiode 21 and by which a predetermined amount of charge determined by the potential of the overflow path 30 is exceeded as a signal charge to the memory part 23 in an exposure period in which all of a plurality of unit pixels simultaneously perform image pickup operation.

Incidentally, in FIG. 3, the structure in which the overflow path 30 is formed by providing the N-impurity diffused region 37 is adopted. However, a structure in which the overflow path 30 is formed by providing a P-impurity diffused region 37 instead of providing the N-impurity diffused region 37 can also be adopted.

### SUMMARY OF THE INVENTION

Variation in potential of the overflow barrier of the overflow path 30 formed in a depleted state between the photodiode 21 and the memory part 23 in the unit pixel 20C of FIG. 3 affects the performance of the solid-state imaging device.

Specifically, the variation in potential of the overflow barrier affects a ratio between a signal quantity read out first and a signal quantity thereafter read out after being retained in the memory part 23, and thus affects the performance of the solid-state imaging device as pixel-by-pixel variation in output image characteristics or variation in maximum amount of retained charge.

FIG. 5 shows a part of the unit pixel 20C of FIG. 3 and the potential of the part. As shown in FIG. 5, the impurity diffused region 37 in which the overflow path 30 is formed is formed by lightly implanting an N-type impurity. The height of the potential of the overflow barrier (OFB) is controlled by the concentration of the impurity in the impurity diffused region 37. As for a method of implanting the impurity, ions (for example an N-type impurity) for forming the overflow path 30 are implanted using a photoresist 50, as shown in FIG. 6.

However, when such an implanting method is used, there inevitably occurs variation in width of the photoresist 50 or variation in accuracy of alignment of the photoresist 50. As a result, because there are N-type impurity regions on both sides of the impurity diffused region 37, the N-type concentration of the part serving as the overflow path 30 is not constant but varies.

As a result, as is clear from the overflow barrier potential diagram of FIG. 6, the variation in the N-type concentration of the part serving as the overflow path 30 appears as variation in potential of the overflow barrier (OFB), and degrades characteristics of the solid-state imaging device.

The present invention has been made in view of such a situation. It is desirable to be able to stably form an overflow barrier that determines a predetermined amount of charge accumulated in a photodiode and flowing out into a memory part.

According to an embodiment of the present invention, there is provided a solid-state imaging device including a plurality of unit pixels, wherein the plurality of unit pixels include: a photoelectric conversion element for generating a charge corresponding to an amount of incident light and internally accumulating the charge; a first transfer gate for transferring the charge accumulated in the photoelectric conversion element; a charge retaining region for retaining the charge transferred from the photoelectric conversion element by the first transfer gate; a second transfer gate for transferring the charge retained in the charge retaining region; and a floating diffusion region for retaining the charge transferred from the charge retaining region by the second transfer gate to read the charge transferred from the charge retaining region by the second transfer gate as a signal; a boundary part between the photoelectric conversion element and the charge retaining region having a structure of an overflow path formed at a potential determining a predetermined amount of charge, the overflow path transferring a charge by which the predetermined amount of charge is exceeded as a signal charge from the photoelectric conversion element to the charge retaining region; and the first transfer gate having two electrodes with different work functions as gate electrodes arranged above the overflow path and above the charge retaining region, respectively.

The work function of the electrode above the overflow path as one of the gate electrodes is smaller than the work function of the electrode above the charge retaining region as the other of the gate electrodes.

The electrode above the overflow path as one of the gate electrodes is N-type polycrystalline silicon, and the electrode above the charge retaining region as the other of the gate electrodes is P-type polycrystalline silicon.

The N-type polycrystalline silicon and the P-type polycrystalline silicon are separated from each other by an insulating layer.

The gate electrodes are of a polycrystalline silicon structure in an identical layer, and are separated into the N-type polycrystalline silicon and the P-type polycrystalline silicon by implantation of different impurities.

The electrode above the overflow path as one of the gate electrodes is an electrode formed of a metal, and the electrode above the charge retaining region as the other of the gate electrodes is P-type polycrystalline silicon.

The electrode above the overflow path as one of the gate electrodes is N-type polycrystalline silicon, and the electrode above the charge retaining region as the other of the gate electrodes is an electrode formed of a metal.

The electrode above the overflow path and the electrode above the charge retaining region as the gate electrodes are electrodes formed of different kinds of metal.

Each electrode of the gate electrodes is connected to identical wiring.

According to an embodiment of the present invention, there is provided a method for manufacturing a first solid-state imaging device, the method including the steps of: forming, in a semiconductor substrate, a charge retaining region for retaining a charge transferred from a photoelectric conversion element for generating the charge corresponding to an amount of incident light and internally accumulating the charge; forming a first gate electrode of a first transfer gate for transferring the charge accumulated in the photoelectric conversion element, the first gate electrode being disposed above the charge retaining region, and a gate electrode of a second transfer gate for transferring the charge retained in the charge retaining region; forming a second gate electrode with a work function different from a work function of the first gate electrode, the second gate electrode being disposed above an overflow path for transferring a charge by which a predetermined amount of charge is exceeded from the photoelectric conversion element to the charge retaining region in a boundary part between the photoelectric conversion element and the charge retaining region; and forming the photoelectric conversion element and a floating diffusion region for retaining the charge transferred from the charge retaining region by the second transfer gate to read the charge transferred from the charge retaining region by the second transfer gate as a signal.

In the method for manufacturing a first solid-state imaging device according to an embodiment of the present invention, a charge retaining region for retaining a charge transferred from a photoelectric conversion element for generating the charge corresponding to an amount of incident light and internally accumulating the charge is formed in a semiconductor substrate, a first gate electrode of a first transfer gate for transferring the charge accumulated in the photoelectric conversion element, the first gate electrode being disposed above the charge retaining region, and a gate electrode of a second transfer gate for transferring the charge retained in the charge retaining region are formed, a second gate electrode with a work function different from a work function of the first gate electrode is formed, the second gate electrode being disposed above an overflow path for transferring a charge by which a predetermined amount of charge is exceeded from the photoelectric conversion element to the charge retaining region in a boundary part between the photoelectric conversion element and the charge retaining region, and the photoelectric conversion element and a floating diffusion region for retaining the charge transferred from the charge retaining region by the second transfer gate to read the charge transferred from the charge retaining region by the second transfer gate as a signal are formed.

According to an embodiment of the present invention, there is provided a method for manufacturing a second solid-state imaging device, the method including the steps of: forming, in a semiconductor substrate, a charge retaining region for retaining a charge transferred from a photoelectric conversion element for generating the charge corresponding to an amount of incident light and internally accumulating the charge; forming a first transfer gate for transferring the charge accumulated in the photoelectric conversion element and a second transfer gate for transferring the charge retained in the charge retaining region; forming the photoelectric conversion element and a floating diffusion region for retaining the charge transferred from the charge retaining region by the second transfer gate to read the charge transferred from the charge retaining region by the second transfer gate as a signal; and implanting ions into parts to become a first gate electrode of the first transfer gate, the first gate electrode being disposed above the charge retaining region, a second gate electrode of the first transfer gate, the second gate electrode having a work function different from a work function of the first gate electrode, and the second gate electrode being disposed above an overflow path for transferring a charge by which a predetermined amount of charge is exceeded from the photoelectric conversion element to the charge retaining region in a boundary part between the photoelectric conversion element and the charge retaining region, and a gate electrode of the second transfer gate.

The step of implanting the ions implants P-type ions into the parts to become the first gate electrode of the first transfer gate and the gate electrode of the second transfer gate after performing patterning by a photoresist, and further implants N-type ions into the second gate electrode of the first transfer gate after performing patterning by a photoresist.

In the method for manufacturing a second solid-state imaging device, a charge retaining region for retaining a charge transferred from a photoelectric conversion element for generating the charge corresponding to an amount of incident light and internally accumulating the charge is formed in a semiconductor substrate, a first transfer gate for transferring the charge accumulated in the photoelectric conversion element and a second transfer gate for transferring the charge retained in the charge retaining region are formed, the photoelectric conversion element and a floating diffusion region for retaining the charge transferred from the charge retaining region by the second transfer gate to read the charge transferred from the charge retaining region by the second transfer gate as a signal are formed, and ions are implanted into parts to become a first gate electrode of the first transfer gate, the first gate electrode being disposed above the charge retaining region, a second gate electrode of the first transfer gate, the second gate electrode having a work function different from a work function of the first gate electrode, and the second gate electrode being disposed above an overflow path for transferring a charge by which a predetermined amount of charge is exceeded from the photoelectric conversion element to the charge retaining region in a boundary part between the photoelectric conversion element and the charge retaining region, and a gate electrode of the second transfer gate.

According to an embodiment of the present invention, there is provided a method for manufacturing a third solid-state imaging device, the method including the steps of: forming, in a semiconductor substrate, a charge retaining region for retaining a charge transferred from a photoelectric conversion element for generating the charge corresponding to an amount of incident light and internally accumulating the charge; forming a first gate electrode of a first transfer gate for transferring the charge accumulated in the photoelectric conversion element, the first gate electrode being disposed above the charge retaining region, and a gate electrode of a second transfer gate for transferring the charge retained in the charge retaining region; forming the photoelectric conversion element and a floating diffusion region for retaining the charge transferred from the charge retaining region by the second transfer gate to read the charge transferred from the charge retaining region by the second transfer gate as a signal; forming a predetermined interlayer insulating film on the semiconductor substrate; etching the interlayer insulating film so that a second gate electrode with a work function different from a work function of the first gate electrode can be disposed, the second gate electrode being to be disposed above an overflow path for transferring a charge by which a predetermined amount of charge is exceeded from the photoelectric conversion element to the charge retaining region in a boundary part between the photoelectric conversion element and the charge retaining region; and forming the second gate electrode by depositing a predetermined insulating film and laminating a predetermined metal in a part formed by etching the interlayer insulating film, the part formed by etching the interlayer insulating film being in a shape in which the second gate electrode can be disposed, and then removing an unnecessary metallic layer.

In the method for manufacturing a third solid-state imaging device, a charge retaining region for retaining a charge transferred from a photoelectric conversion element for generating the charge corresponding to an amount of incident light and internally accumulating the charge is formed in a semiconductor substrate, a first gate electrode of a first transfer gate for transferring the charge accumulated in the photoelectric conversion element, the first gate electrode being disposed above the charge retaining region, and a gate electrode of a second transfer gate for transferring the charge retained in the charge retaining region are formed, the photoelectric conversion element and a floating diffusion region for retaining the charge transferred from the charge retaining region by the second transfer gate to read the charge transferred from the charge retaining region by the second transfer gate as a signal are formed, a predetermined interlayer insulating film is formed on the semiconductor substrate, the interlayer insulating film is etched so that a second gate electrode with a work function different from a work function of the first gate electrode can be disposed, the second gate electrode being to be disposed above an overflow path for transferring a charge by which a predetermined amount of charge is exceeded from the photoelectric conversion element to the charge retaining region in a boundary part between the photoelectric conversion element and the charge retaining region, and the second gate electrode is formed by depositing a predetermined insulating film and laminating a predetermined metal in a part formed by etching the interlayer insulating film, the part formed by etching the interlayer insulating film being in a shape in which the second gate electrode can be disposed, and then removing an unnecessary metallic layer.

According to an embodiment of the present invention, there is provided a method for manufacturing a fourth solid-state imaging device, the method including the steps of: forming, in a semiconductor substrate, a charge retaining region for retaining a charge transferred from a photoelectric conversion element for generating the charge corresponding to an amount of incident light and internally accumulating the charge; forming a gate electrode of a second transfer gate for transferring the charge retained in the charge retaining region; forming the photoelectric conversion element and a floating diffusion region for retaining the charge transferred from the charge retaining region by the second transfer gate to read the charge transferred from the charge retaining region by the second transfer gate as a signal; forming a predetermined interlayer insulating film on the semiconductor substrate; etching the interlayer insulating film so that a first gate electrode of a first transfer gate for transferring the charge accumulated in the photoelectric conversion element, the first gate electrode being to be disposed above the charge retaining region, can be disposed; forming the first gate electrode by depositing a predetermined insulating film and laminating a first metal in a part formed by etching the interlayer insulating film, the part formed by etching the interlayer insulating film being in a shape in which the first gate electrode can be disposed, and then removing an unnecessary metallic layer; etching the interlayer insulating film so that a second gate electrode with a work function different from a work function of the first gate electrode can be disposed, the second gate electrode being to be disposed above an overflow path for transferring a charge by which a predetermined amount of charge is exceeded from the photoelectric conversion element to the charge retaining region in a boundary part between the photoelectric conversion element and the charge retaining region; and forming the second gate electrode by depositing a predetermined insulating film and laminating a second metal different from the first metal in a part formed by etching the interlayer insulating film, the part formed by etching the interlayer insulating film being in a shape in which the second gate electrode can be disposed, and then removing an unnecessary metallic layer.

In the method for manufacturing a fourth solid-state imaging device, a charge retaining region for retaining a charge transferred from a photoelectric conversion element for generating the charge corresponding to an amount of incident light and internally accumulating the charge is formed in a semiconductor substrate, a gate electrode of a second transfer gate for transferring the charge retained in the charge retaining region is formed, the photoelectric conversion element and a floating diffusion region for retaining the charge transferred from the charge retaining region by the second transfer gate to read the charge transferred from the charge retaining region by the second transfer gate as a signal are formed, a predetermined interlayer insulating film is formed on the semiconductor substrate, the interlayer insulating film is etched so that a first gate electrode of a first transfer gate for transferring the charge accumulated in the photoelectric conversion element, the first gate electrode being to be disposed above the charge retaining region, can be disposed, the first gate electrode is formed by depositing a predetermined insulating film and laminating a first metal in a part formed by etching the interlayer insulating film, the part formed by etching the interlayer insulating film being in a shape in which the first gate electrode can be disposed, and then removing an unnecessary metallic layer, the interlayer insulating film is etched so that a second gate electrode with a work function different from a work function of the first gate electrode can be disposed, the second gate electrode being to be disposed above an overflow path for transferring a charge by which a predetermined amount of charge is exceeded from the photoelectric conversion element to the charge retaining region in a boundary part between the photoelectric conversion element and the charge retaining region, and the second gate electrode is formed by depositing a predetermined insulating film and laminating a second metal different from the first metal in a part formed by etching the interlayer insulating film, the part formed by etching the interlayer insulating film being in a shape in which the second gate electrode can be disposed, and then removing an unnecessary metallic layer.

According to an embodiment of the present invention, there is provided an electronic apparatus mounted on a solid-state imaging device, wherein the solid-state imaging device includes a plurality of unit pixels, the plurality of unit pixels including: a photoelectric conversion element for generating a charge corresponding to an amount of incident light and internally accumulating the charge; a first transfer gate for transferring the charge accumulated in the photoelectric conversion element; a charge retaining region for retaining the charge transferred from the photoelectric conversion element by the first transfer gate; a second transfer gate for transferring the charge retained in the charge retaining region; and a floating diffusion region for retaining the charge transferred from the charge retaining region by the second transfer gate to read the charge transferred from the charge retaining region by the second transfer gate as a signal; a boundary part between the photoelectric conversion element and the charge retaining region having a structure of an overflow path formed at a potential determining a predetermined amount of charge, the overflow path transferring a charge by which the predetermined amount of charge is exceeded as a signal charge from the photoelectric conversion element to the charge retaining region; and the first transfer gate having two electrodes with different work functions as gate electrodes arranged above the overflow path and above the charge retaining region, respectively.

According to an embodiment of the present invention, an overflow barrier can be formed stably.

### BRIEF DESCRIPTION OF THE DRAWINGS

FIG. 1 is a diagram showing a constitution of an existing unit pixel;

FIG. 2 is a diagram showing a constitution of an existing unit pixel;

FIG. 3 is a diagram showing a constitution of an existing unit pixel;

FIG. 4 is a potential diagram showing potential in an X-direction of the unit pixel in FIG. 3;

FIG. 5 is a diagram of assistance in explaining the potential of an overflow barrier in an existing unit pixel;

FIG. 6 is a diagram of assistance in explaining a method of impurity implantation;

FIG. 7 is a block diagram showing an example of constitution of an embodiment of a solid-state imaging device to which the present invention is applied;

FIG. 8 is a diagram showing a constitution of a unit pixel of a solid-state imaging device to which the embodiment of the present invention is applied;

FIG. 9 is a diagram of a structure in an X-direction of the unit pixel in FIG. 8;

FIGS. 10A, 10B, 10C, and 10D are diagrams of assistance in explaining a method for manufacturing the unit pixel in FIG. 8;

FIG. 11 is a diagram showing a constitution of a unit pixel of a solid-state imaging device to which the embodiment of the present invention is applied;

FIGS. 12A, 12B, 12C, 12D, 12E, 12F, and 12G are diagrams of assistance in explaining a method for manufacturing the unit pixel in FIG. 11;

FIG. 13 is a diagram showing a constitution of a unit pixel of a solid-state imaging device to which the embodiment of the present invention is applied;

FIGS. 14A, 14B, 14C, 14D, 14E, 14F, 14G, and 14H are diagrams of assistance in explaining a method for manufacturing the unit pixel in FIG. 13;

FIG. 15 is a diagram of assistance in explaining the method for manufacturing the unit pixel in FIG. 13;

FIG. 16 is a diagram showing a constitution of a unit pixel of a solid-state imaging device to which the embodiment of the present invention is applied;

FIGS. 17A, 17B, 17C, 17D, and 17E are diagrams of assistance in explaining a method for manufacturing the unit pixel in FIG. 16; and

FIG. 18 is a block diagram showing an example of constitution of an embodiment of an electronic apparatus to which the present invention is applied.

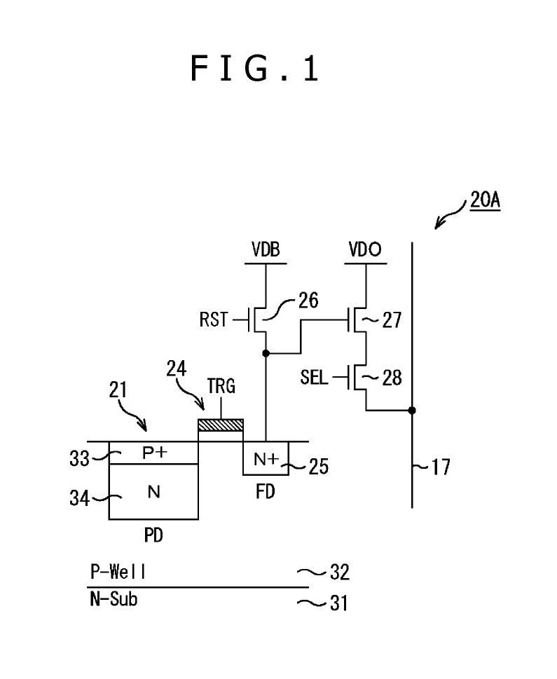

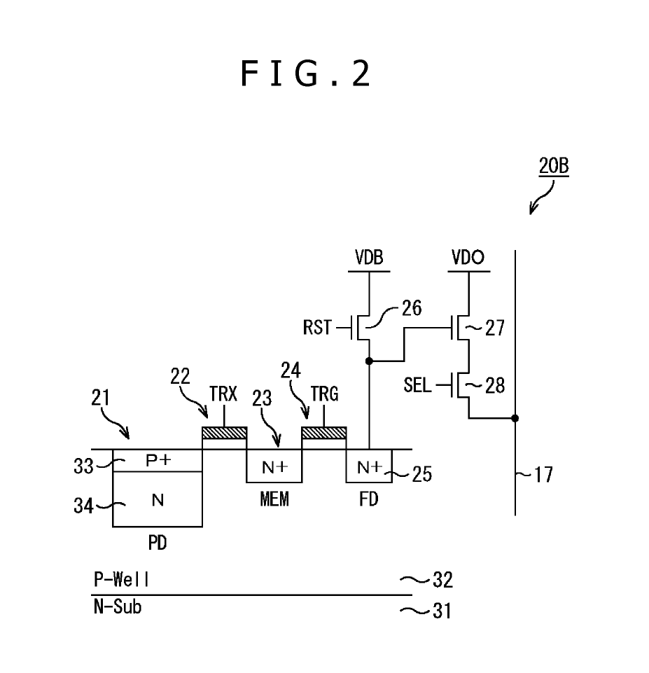

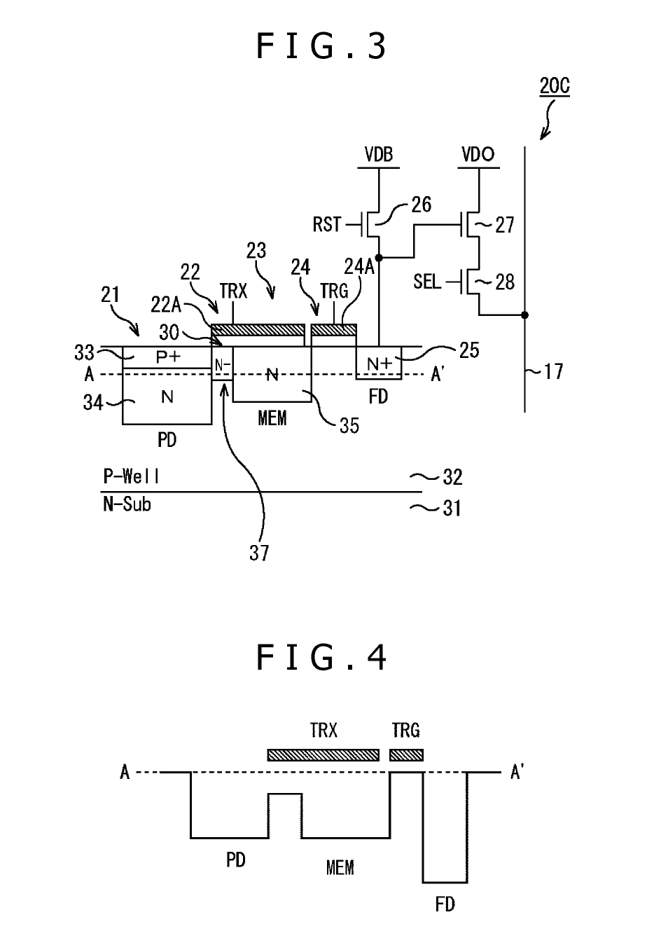

### DETAILED DESCRIPTION OF THE PREFERRED EMBODIMENTS

A mode for carrying out the invention (which mode will hereinafter be referred to as embodiments) will hereinafter be described. Incidentally, description will be made in the following order.

### 1. First Embodiment

### 2. Second Embodiment

### 3. Third Embodiment

### 4. Fourth Embodiment

### 5. Examples of Modification

### 1. First Embodiment

### Example of Constitution of Solid-State Imaging Device

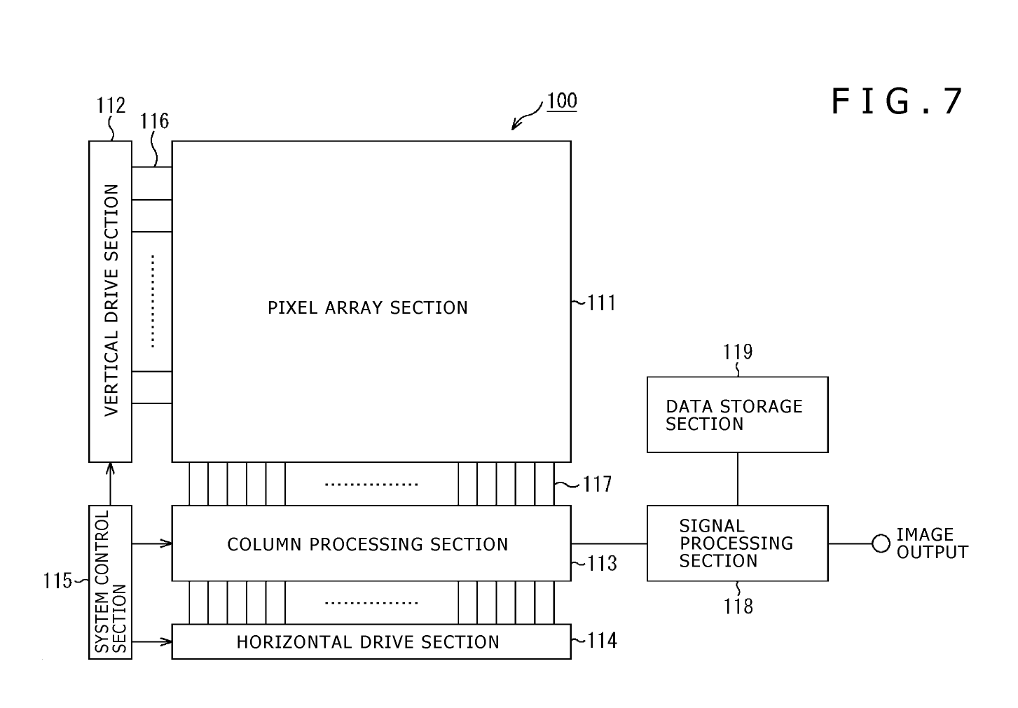

FIG. 7 is a block diagram showing an example of constitution of a CMOS image sensor as a solid-state imaging device to which an embodiment of the present invention is applied.

The CMOS image sensor 100 includes a pixel array section 111, a vertical drive section 112, a column processing section 113, a horizontal drive section 114, and a system control section 115. The pixel array section 111, the vertical drive section 112, the column processing section 113, the horizontal drive section 114, and the system control section 115 are formed on a semiconductor substrate (chip) not shown in FIG. 7.

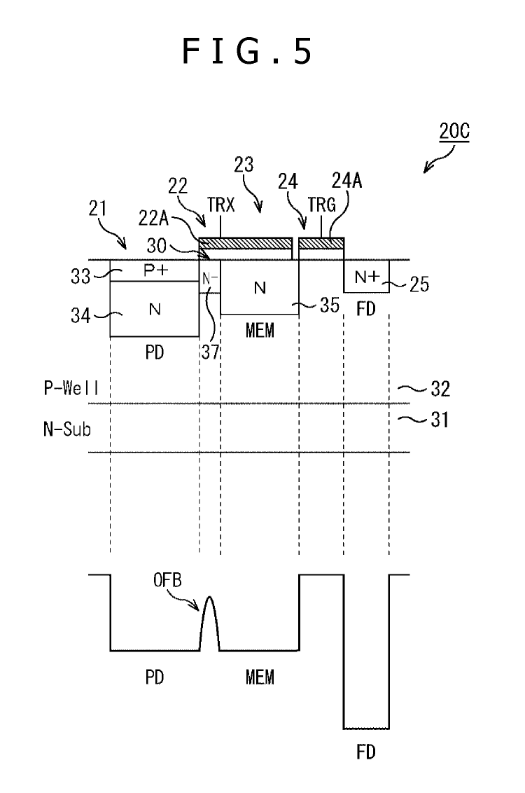

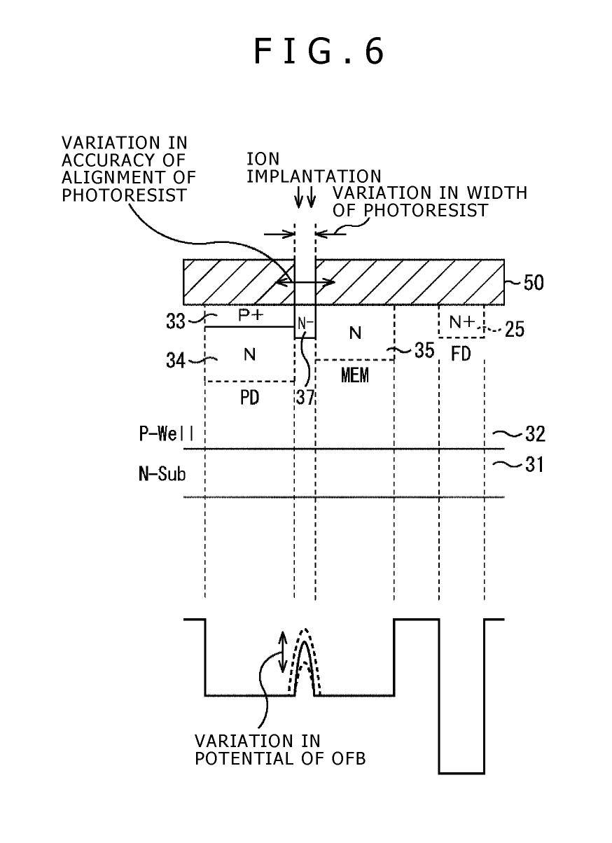

In the pixel array section 111, unit pixels (unit pixels 120 in FIG. 5) having a photoelectric conversion element for generating a light charge whose amount corresponds to an amount of incident light (which light charge may hereinafter be referred to simply as a “charge”) and accumulating the light charge within the photoelectric conversion element are two-dimensionally arranged in the form of a matrix. Incidentally, in the following, the light charge may be referred to simply as a “charge,” and the unit pixels may be referred to simply as “pixels.”

The pixel array section 111 further has a pixel driving line 116 formed for each row of the pixel arrangement in the form of a matrix along a horizontal direction of FIG. 7 (direction of arrangement of pixels of pixel rows) and a vertical signal line 117 formed for each column of the pixel arrangement in the form of a matrix along a vertical direction of FIG. 7 (direction of arrangement of pixels of pixel columns). While FIG. 7 shows single pixel driving lines 116, the pixel driving lines 116 are not limited to single lines. One terminal of the pixel driving lines 116 is connected to output terminals corresponding to the respective rows of the vertical drive section 112.

The CMOS image sensor 100 further includes a signal processing section 118 and a data storage section 119. The signal processing section 118 and the data storage section 119 may be realized by an external signal processing section provided on a substrate separate from the CMOS image sensor 100, for example a DSP (Digital Signal Processor) or processing by software, or may be mounted on the same substrate as the CMOS image sensor 100.

The vertical drive section 112 is formed by a shift register, an address decoder or the like. The vertical drive section 112 is a pixel drive section for driving each pixel of the pixel array section 111 on an all-pixel simultaneous basis or in row units, for example. Though a concrete constitution of the vertical drive section 112 is not shown, the vertical drive section 112 generally has two scanning systems, that is, a readout scanning system and a sweep-out scanning system.

The readout scanning system sequentially selects and scans the unit pixels of the pixel array section 111 in row units to read out signals from the unit pixels. The sweep-out scanning system performs sweep-out scanning of a readout row to be subjected to readout scanning by the readout scanning system, the sweep-out scanning preceding the readout scanning by a time corresponding to a shutter speed.

The sweep-out scanning by the sweep-out scanning system sweeps out an unnecessary charge from the photoelectric conversion elements of the unit pixels in the readout row (resets the photoelectric conversion elements). Then, a so-called electronic shutter operation is performed by the sweeping out of the unnecessary charges (reset) by the sweep-out scanning system. The electronic shutter operation in this case refers to an operation of discarding the light charges of the photoelectric conversion elements and starting new light exposure (starting accumulating light charges).

A signal read out by a readout operation of the readout scanning system corresponds to an amount of light incident after an immediately preceding readout operation or the electronic shutter operation. A period from the readout timing of the immediately preceding readout operation or the sweep-out timing of the electronic shutter operation to the readout timing of the present readout operation is a time (exposure time) of accumulation of a light charge in unit pixels.

The pixel signal output from each unit pixel of a pixel row selected and scanned by the vertical drive section 112 is supplied to the column processing section 113 through each of the vertical signal lines 117. The column processing section 113 subjects the pixel signal output from each unit pixel of the selected row through the vertical signal line 117 to predetermined signal processing for each pixel column of the pixel array section 111, and temporarily retains the pixel signal after the signal processing.

Specifically, the column processing section 113 performs at least noise removal processing, for example CDS (Correlated Double Sampling) as the signal processing. The CDS processing of the column processing section 113 removes reset noise, fixed pattern noise unique to pixels such as variations in threshold value of amplifying transistors, and the like. The column processing section 113 can be provided with for example an AD (Analog-to-Digital) converting function in addition to the noise removal processing function to output a signal level as a digital signal.

The horizontal drive section 114 is formed by a shift register, an address decoder or the like. The horizontal drive section 114 selects unit circuits corresponding to the pixel columns of the column processing section 113 in order. The pixel signals resulting from the signal processing in the column processing section 113 are output to the signal processing section 118 in order by the selection and scanning of the horizontal drive section 114.

The system control section 115 is formed by a timing generator or the like for generating various timing signals. The system control section 115 performs driving control on the vertical drive section 112, the column processing section 113, and the horizontal drive section 114, for example, on the basis of the various timing signals generated by the timing generator.

The signal processing section 118 has at least an addition processing function. The signal processing section 118 subjects the pixel signals output from the column processing section 113 to various signal processing such as addition processing and the like. The data storage section 119 temporarily stores data necessary for the signal processing in the signal processing section 118 at the time of the signal processing in the signal processing section 118.

### [Structure of Unit Pixel]

A concrete structure of the unit pixels 120 arranged in the form of a matrix in the pixel array section 111 in FIG. 7 will next be described. A unit pixel 120 has a pixel structure in which a photodiode and a memory part as described earlier are integrated with each other by an overflow path. In present embodiments, constitutions of unit pixels 120A to 120D (a first to a fourth embodiment) will be described as examples of constitution of the unit pixel 120. In the first embodiment, the unit pixel 120A will be described.

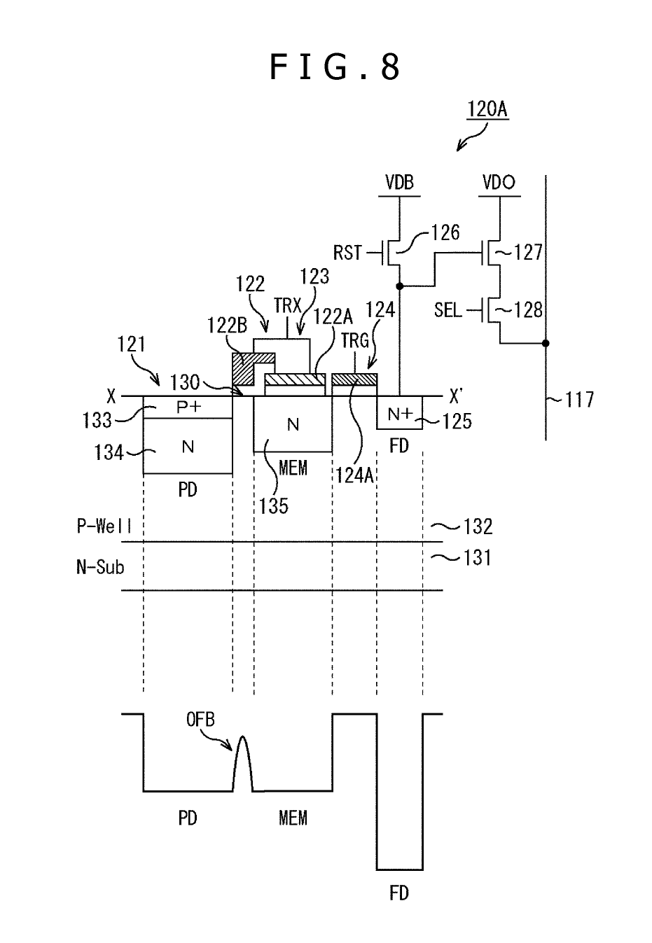

FIG. 8 is a diagram showing a constitution of the unit pixel 120A.

The unit pixel 120A has for example a photodiode (PD) 121 as a photoelectric conversion element. The photodiode 121 is for example a buried type photodiode formed by burying an N-type buried layer 134 with a P-type layer 133 formed on the side of a substrate surface in a P-type well layer 132 formed on an N-type substrate 131.

In addition to the photodiode 121, the unit pixel 120A has a first transfer gate 122, a memory part (MEM) 123, a second transfer gate 124, and a floating diffusion region (FD) 125. Incidentally, the memory part 123 and the floating diffusion region 125 are shielded from light.

The first transfer gate transfers a charge resulting from photoelectric conversion by the photodiode 121 and accumulated in the photodiode 121 when a transfer pulse TRX is applied to a gate electrode 122A and a gate electrode 122B.

Specifically, the gate electrode 122A is formed of P-type Poly-Si (P-type polycrystalline silicon (polycrystalline Si)), and is disposed above the memory part 123. On the other hand, the gate electrode 122B is formed of N-type Poly-Si (N-type polycrystalline silicon), and is disposed above a part serving as an overflow path 130 formed in a boundary part between the photodiode (PD) 121 and the memory part (MEM) 123. Incidentally, no problem is presented even when the gate electrode 122B is disposed having a certain overlapping part overlapping the photodiode 121 or the memory part 123 other than the part serving as the overflow path 130.

The respective Poly-Si (polycrystalline silicon) parts of the gate electrode 122A and the gate electrode 122B are separated from each other by an insulating film (insulating layer), but are electrically connected to same wiring (TRX). The P-type Poly-Si forming the gate electrode 122A and the N-type Poly-Si forming the gate electrode 122B are insulated from each other by an oxide film.

The memory part 123 is formed by an N-type buried channel 135 formed below the gate electrode 122A. The memory part 123 accumulates the charge transferred from the photodiode 121 by the first transfer gate 122. Incidentally, the memory part 123 is formed with such an impurity concentration as to be in a depleted state when the charge is transferred (discharged) by the second transfer gate 124.

In the unit pixel 120A, the photodiode 121 and the memory part 123 are formed as an N-type impurity diffused region within the P-type well layer 132 formed on the N-type substrate 131. For example, when the P-type impurity concentration of the P-type well layer 132 in this case is 1×10¹⁵ (cm⁻³), the photodiode 121 and the memory part 123 are formed with such an N-type impurity concentration as to be in a depleted state at a time of charge discharge, for example a concentration of about 1×10¹⁶ (cm⁻³) to 1×10¹⁷ (cm⁻³). In addition, the P-type layer 133 formed on the substrate surface side of the photodiode 121 is formed with an impurity concentration of about 1×10¹⁷ (cm⁻³) to 1×10¹⁹ (cm⁻³), for example.

The second transfer gate 124 is formed between the memory part (MEM) 123 and the floating diffusion region (FD) 125. The second transfer gate 124 transfers the charge accumulated in the memory part 123 when a transfer pulse TRG is applied to a gate electrode 124A. The floating diffusion region 125 is a charge-to-voltage converting part formed of an N-type layer. The floating diffusion region 125 converts the charge transferred from the memory part 123 by the second transfer gate 124 into a voltage.

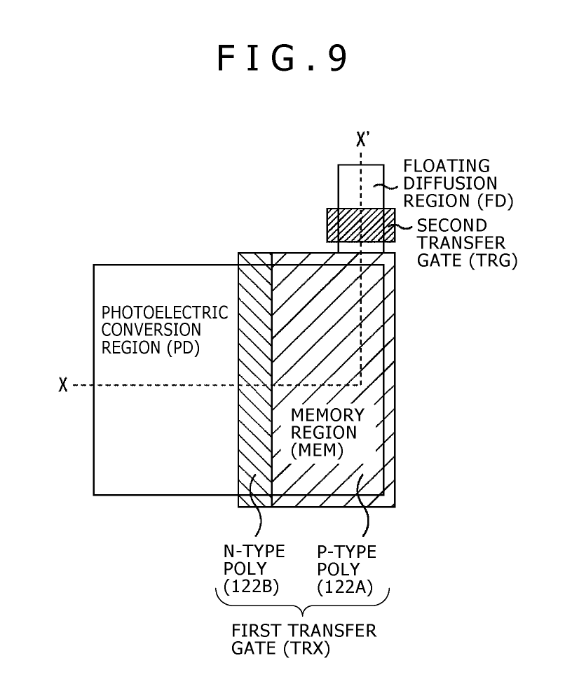

FIG. 9 is a diagram of a structure in an X-direction of the unit pixel 120A in FIG. 8.

As shown in FIG. 9, a memory region (MEM) in which the memory part 123 is formed is covered by the gate electrode 122A made of P-type Poly-Si. On the other hand, the P-type well layer 132 is situated below the gate electrode 122B made of N-type Poly-Si. An overflow barrier (OFB) can be formed from a difference between the work functions of the P-type Poly-Si of the gate electrode 122A and the N-type Poly-Si of the gate electrode 122B.

Returning to the description of FIG. 8, the unit pixel 120A further includes a reset transistor 126, an amplifying transistor 127, and a selecting transistor 128. In the example of FIG. 8, an N-channel MOS transistor is used as the reset transistor 126, the amplifying transistor 127, and the selecting transistor 128. However, a combination of conduction types of the reset transistor 126, the amplifying transistor 127, and the selecting transistor 128 illustrated in FIG. 8 is a mere example, and is not limited to the combination of these conduction types.

The reset transistor 126 is connected between a power supply VDB and the floating diffusion region 125. The reset transistor 126 resets the floating diffusion region 125 when a reset pulse RST is applied to the gate electrode of the reset transistor 126. The amplifying transistor 127 has a drain electrode connected to a power supply VDO, and has a gate electrode connected to the floating diffusion region 125. The amplifying transistor 127 reads out the voltage of the floating diffusion region 125.

The selecting transistor 128 for example has a drain electrode connected to the source electrode of the amplifying transistor 127 and has a source electrode connected to a vertical signal line 117. The selecting transistor 128 selects the unit pixel 120 from which to read out a pixel signal when a selecting pulse SEL is applied to the gate electrode of the selecting transistor 128. Incidentally, the selecting transistor 128 can also be connected between the power supply VDO and the drain electrode of the amplifying transistor 127.

Incidentally, it is also possible to omit one or a plurality of the reset transistor 126, the amplifying transistor 127, and the selecting transistor 128 according to a method of reading out the pixel signal, or share one or a plurality of the reset transistor 126, the amplifying transistor 127, and the selecting transistor 128 between a plurality of pixels.

The unit pixel 120A further includes a charge discharging part (not shown) for discharging the charge accumulated in the photodiode 121. The charge discharging part discharges the charge of the photodiode 121 into the drain part of an N-type layer when a control pulse ABG is applied to the gate electrode of the charge discharging part at a time of a start of light exposure. The charge discharging part acts to prevent an overflow of charge when the photodiode 121 saturates during a readout period after an end of the light exposure. A predetermined voltage VDA is applied to the drain part.

### [Potentials of Gate Electrodes Above Memory Part]

The potentials of the gate electrodes above the memory part 123 as a charge retaining region, that is, the gate electrode 122A and the gate electrode 122B of the first transfer gate 122 will be described in the following.

When the transfer pulse TRX is applied to the gate electrode 122A and the gate electrode 122B, the potential of the part serving as the overflow path 130 is depressed because the work function of the N-type Poly-Si forming the gate electrode 122B is smaller than the work function of the P-type Poly-Si forming the gate electrode 122A. That is, when the same voltage (transfer pulse TRX) is applied to the gate electrode 122A and the gate electrode 122B, a bias voltage of about 1 V, for example, is applied to the side of the gate electrode 122B. As a result, in terms of potential, an offset voltage is applied from the upper side. Thus, the potential of the P-type well layer 132 formed under the gate electrode 122B is lowered, and the overflow path 130 is formed.

In other words, when the gate electrode 122B is disposed above the P-type well layer 132, and the transfer pulse TRX is applied to the gate electrode 122A and the gate electrode 122B, modulation can be applied to the P-type well layer 132 by an offset between the gate electrode 122A and the gate electrode 122B. That is, by applying the transfer pulse TRX to the gate electrode 122A and the gate electrode 122B, the potential of the overflow barrier (OFB) formed by the P-type well layer 132 in the boundary part between the photodiode (PD) 121 and the memory part (MEM) 123 is deepened, and the overflow path 130 is formed.

Incidentally, as the transfer pulse TRX, 0 V or a negative potential, for example, is applied when the overflow path 130 is formed by controlling the height of the potential of the overflow barrier (OFB).

### [Manufacturing Processes]

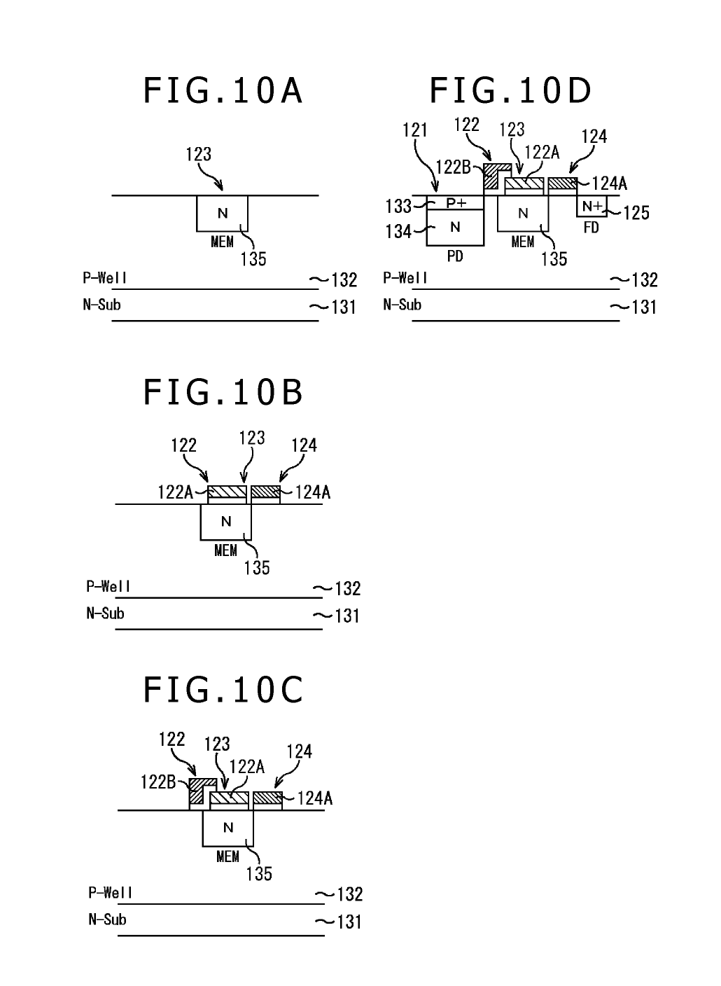

Processes for manufacturing the unit pixel 120A of FIG. 8 will next be described with reference to FIGS. 10A to 10D.

First, as shown in FIG. 10A, an ion implantation process is performed to form a memory part (MEM) 123 as an N-type region in a P-type well layer 132 formed on an N-type substrate 131. The N-type impurity concentration of the memory part 123 formed at this time is the concentration described earlier.

Next, as shown in FIG. 10B, a thermal oxidation process is performed to form a silicon oxide film (Si oxide film), and thereafter a Poly-Si film is formed and a patterning process is performed to form the gate electrode 122A of a first transfer gate 122 and the gate electrode 124A of a second transfer gate 124. Before this patterning, however, an ion implantation process is performed so that the gate electrode 122A and the gate electrode 124A are formed so as to have a P-type impurity concentration. The gate electrode 122A made of P-type Poly-Si is thereby disposed above the memory part 123.

Incidentally, in this example of the manufacturing processes, description has been made of an example in which ion implantation is performed before patterning. However, ions may be implanted only into the gate electrode 122A using a photomask in a final stage of the manufacturing processes. On the other hand, as for the gate electrode 124A, the gate electrode 124A may be formed as a P-type simultaneously with the gate electrode 122A, or may be formed as an N-type by ion implantation after the gate electrode 124A is formed.

Next, as shown in FIG. 10C, a thermal oxidation process or a lamination process is performed to form a silicon oxide film, and thereafter a gate electrode 122B is formed by forming a Poly-Si film again and performing etching so as to obtain a desired pattern. Thereby, the gate electrode 122B made of N-type Poly-Si is disposed above a part serving as an overflow path 130.

Finally, as shown in FIG. 10D, an ion implantation process is performed to form a photodiode (PD) 121 and a floating diffusion region (FD) 125 in the P-type well layer 132 formed on the N-type substrate 131. The impurity concentration of the photodiode 121 formed at this time is the concentration described earlier. A CMOS image sensor 100 having the unit pixel 120A of FIG. 8 can be obtained by thereafter undergoing predetermined known manufacturing processes such as a thermal process for impurity activation and the like.

As described above, in the first embodiment, the gate electrode 122A made of P-type Poly-Si and the gate electrode 122B made of N-type Poly-Si are disposed as gate electrodes with different work functions which gate electrodes are disposed above the memory part 123 and the overflow path 130. An offset between the gate electrodes depresses the potential of the P-type well layer 132 in the boundary part between the photodiode 121 and the memory part 123, and thereby forms the overflow path 130.

Thereby, the overflow path 130 can be formed by providing the plurality of gate electrodes without providing an impurity diffused region in the part serving as the overflow path 130. An overflow barrier (intermediate overflow barrier) can therefore be formed stably. In addition, because the potential is depressed by the offset between the gate electrodes, the potential can be controlled more robustly than in a case where the height of the potential of the overflow barrier is controlled by impurity concentration.

Incidentally, in the description of FIG. 8 and FIGS. 10A to 10D, the gate electrode 122B has such a structure as to ride over the gate electrode 122A. However, the gate electrode 122B does not need to have such a structure. It suffices for the gate electrode 122B to be disposed in the boundary part between the photodiode 121 and the memory part 123. In addition, the P-type and the N-type of conductors forming the impurity diffused regions and the gate electrodes in the unit pixel 120A of FIG. 8 may be interchanged.

### 2. Second Embodiment

### Structure of Unit Pixel

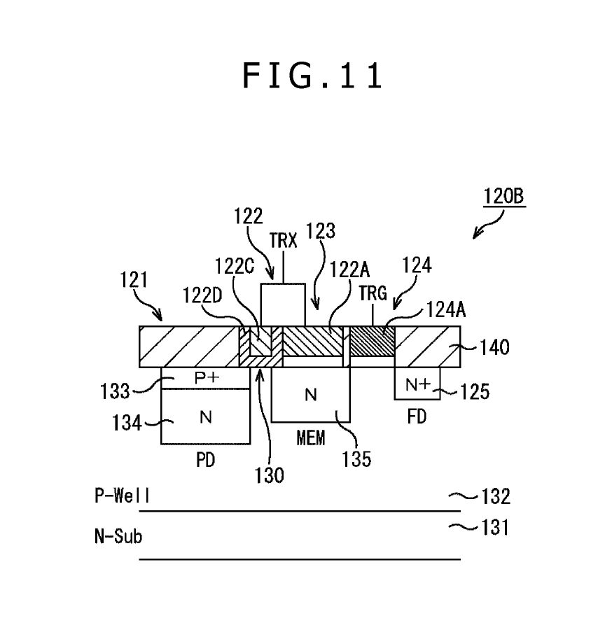

A second embodiment of the present invention will next be described with reference to FIG. 11. The second embodiment is different from the first embodiment in that one of the two gate electrodes formed by polycrystalline silicon in the first embodiment is formed by a metal in the second embodiment.

FIG. 11 is a diagram showing a constitution of a unit pixel 120B. Incidentally, in FIG. 11, parts corresponding to those of FIG. 8 are identified by the same reference symbols, and description thereof will be omitted as appropriate.

In the unit pixel 120B, an interlayer insulating film 140 is formed on a P-type well layer 132, while a gate electrode 122A made of P-type Poly-Si (polycrystalline silicon) is formed above a memory part 123. In addition, a metallic gate 122C laminated on a gate insulating film 122D is formed above a part serving as an overflow path 130 in a boundary part between a photodiode (PD) 121 and a memory part (MEM) 123.

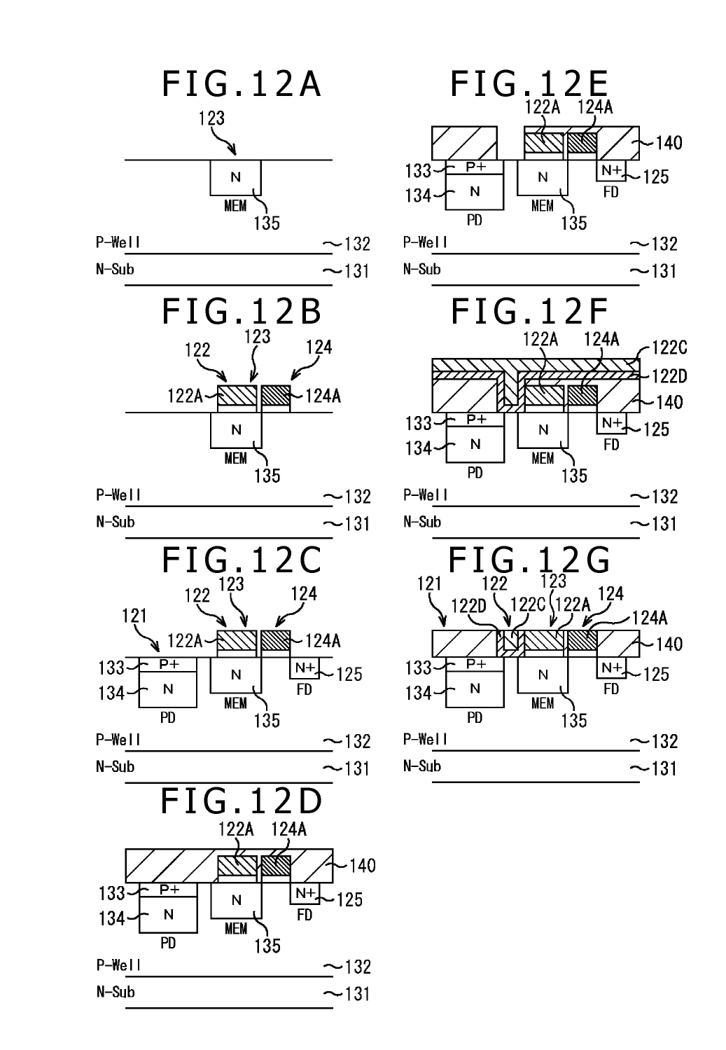

Specifically, in the unit pixel 120B, after the gate electrode 122A is formed, the interlayer insulating film 140 is formed, a part of the interlayer insulating film 140 under which part the overflow path 130 is formed is subjected to etching, the gate insulating film 122D and the metallic gate 122C are laminated in the part of the interlayer insulating film 140, and thereafter an upper part of the gate insulating film 122D and the metallic gate 122C is removed by chemical mechanical polishing (CMP), whereby a gate electrode is formed. This process is referred to as a damascene process. Details of the process will be described in a section of the processes for manufacturing the unit pixel 120B in FIGS. 12A to 12G.

The metallic gate 122C is for example formed by metals selected from a group including hafnium (Hf), tantalum (Ta), and the like, alloys containing these metals, or compounds of these metals. The work function of the metallic gate 122C is close to the work function of N-type Poly-Si. Specifically, a material having a work function of 4.6 eV or less, or preferably a work function of 4.3 eV or less, is suitable as the metallic gate 122C. HfSix, in particular, is desirably used as the metallic gate 122C.

A silicon oxide film or a high dielectric constant insulating film such as hafnium oxide (HfO₂) or the like is used as the gate insulating film 122D.

In the unit pixel 120B formed as described above, when a transfer pulse TRX is applied to the gate electrode 122A and the metallic gate 122C, the potential of the part serving as the overflow path 130 is depressed because the work function of the metallic gate 122C (for example HfSix) is smaller than the work function of the gate electrode 122A (P-type Poly-Si).

### [Manufacturing Processes]

Processes for manufacturing the unit pixel 120B of FIG. 11 will next be described with reference to FIGS. 12A to 12G.

First, as shown in FIG. 12A, an ion implantation process is performed to form a memory part (MEM) 123 as an N-type region in a P-type well layer 132 formed on an N-type substrate 131.

Next, as shown in FIG. 12B, a thermal oxidation process is performed to form a silicon oxide film, and thereafter a Poly-Si film is formed and a patterning process is performed to form the gate electrode 122A of a first transfer gate 122 and the gate electrode 124A of a second transfer gate 124. Before this patterning, however, an ion implantation process is performed so that the gate electrode 122A and the gate electrode 124A are formed so as to have a P-type impurity concentration. The gate electrode 122A made of P-type Poly-Si is thereby disposed above the memory part 123.

Incidentally, in this example of the manufacturing processes, description has been made of an example in which ion implantation is performed before patterning. However, ions may be implanted only into the gate electrode 122A using a photomask in a final stage of the manufacturing processes. On the other hand, as for the gate electrode 124A, the gate electrode 124A may be formed as a P-type simultaneously with the gate electrode 122A, or may be formed as an N-type by ion implantation after the gate electrode 124A is formed.

Next, as shown in FIG. 12C, an ion implantation process is performed to form a photodiode (PD) 121 and a floating diffusion region (FD) 125 in the P-type well layer 132 formed on the N-type substrate 131. The impurities are activated by a thermal process.

Thereafter, as shown in FIG. 12D, an interlayer insulating film 140 is formed on the surface side of the P-type well layer 132 after the photodiode (PD) 121, the gate electrode 122A of the first transfer gate 122, the memory part (MEM) 123, the second transfer gate 124, and the floating diffusion region (FD) 125 are formed. Then, in a photolithographic process and a dry etching process, as shown in FIG. 12E, the interlayer insulating film 140 is etched for a part in which to form a gate electrode above a boundary part between the photodiode (PD) 121 and the memory part (MEM) 123.

Then, as shown in FIG. 12F, a gate insulating film 122D formed by a silicon oxide film or a high dielectric constant insulating film is deposited on the part processed into a predetermined shape by the etching, and a metallic gate 122C made of HfSix or the like is further laminated. Then, in a chemical mechanical polishing process, a damascene process for removing an unnecessary metallic layer in an upper part of the metallic gate 122C and the gate insulating film 122D is performed. The metallic gate 122C laminated on the gate insulating film 122D as shown in FIG. 12G is thus formed. The metallic gate 122C made of HfSix or the like is thereby disposed above the part serving as the overflow path 130.

A CMOS image sensor 100 having the unit pixel 120B of FIG. 11 can be obtained by thereafter undergoing predetermined known manufacturing processes. As described above, in the second embodiment, the gate electrode 122A made of P-type Poly-Si and the metallic gate 122C made of a metal (for example HfSix) corresponding to N-type Poly-Si are disposed as gate electrodes with different work functions which gate electrodes are disposed above the memory part 123 and the overflow path 130. An offset between the gate electrodes depresses the potential of the P-type well layer 132 in the boundary part between the photodiode 121 and the memory part 123, and thereby forms the overflow path 130.

Incidentally, the P-type and the N-type of conductors forming the impurity diffused regions and the gate electrodes in the unit pixel 120B of FIG. 11 may be interchanged. When the P-type and the N-type of the conductors forming the impurity diffused regions and the gate electrodes in the unit pixel 120B of FIG. 11 are interchanged, the work function desired for the metallic electrode also becomes the opposite.

### 3. Third Embodiment

### Structure of Unit Pixel

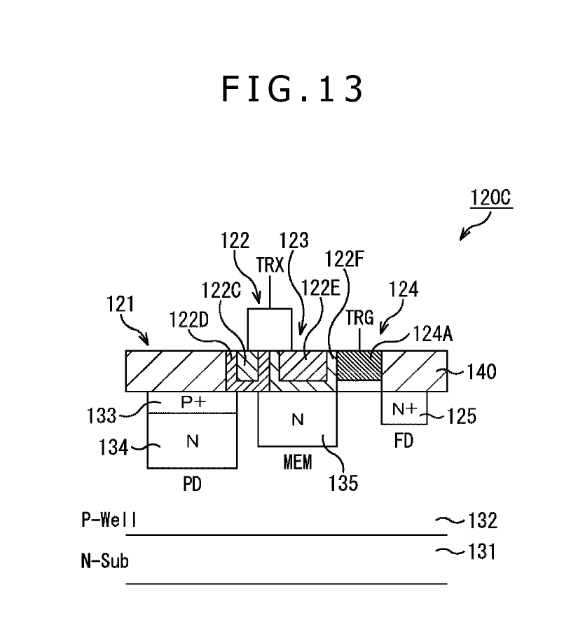

A third embodiment of the present invention will next be described with reference to FIG. 13. The third embodiment is different from the first embodiment in that the two gate electrodes formed by polycrystalline silicon in the first embodiment are both formed by a metal in the third embodiment.

FIG. 13 is a diagram showing a constitution of a unit pixel 120C. Incidentally, in FIG. 13, parts corresponding to those of FIG. 8 and FIG. 11 are identified by the same reference symbols, and description thereof will be omitted as appropriate.

In the unit pixel 120C, an interlayer insulating film 140 is formed on a P-type well layer 132, while a metallic gate 122E laminated on a gate insulating film 122F is formed above a memory part 123, and a metallic gate 122C laminated on a gate insulating film 122D is formed above a part serving as an overflow path 130.

The metallic gate 122E is for example formed by metals selected from a group including titanium (Ti), molybdenum (Mo), ruthenium (Ru), and the like, alloys containing these metals, or compounds of these metals. The work function of the metallic gate 122E is close to the work function of P-type Poly-Si. Specifically, a material having a work function of 4.6 eV or more, or preferably a work function of 4.9 eV or more, is suitable as the metallic gate 122E. Titanium nitride (TiN) or ruthenium (Ru), in particular, is desirably used as the metallic gate 122E.

A silicon oxide film or a high dielectric constant insulating film is used as the gate insulating film 122F.

In the unit pixel 120C formed as described above, when a transfer pulse TRX is applied to the metallic gate 122E and the metallic gate 122C, the potential of the part serving as the overflow path 130 is depressed because the work function of the metallic gate 122C (for example HfSix) is smaller than the work function of the metallic gate 122E (for example titanium nitride (TiN) or the like).

### [Manufacturing Processes]

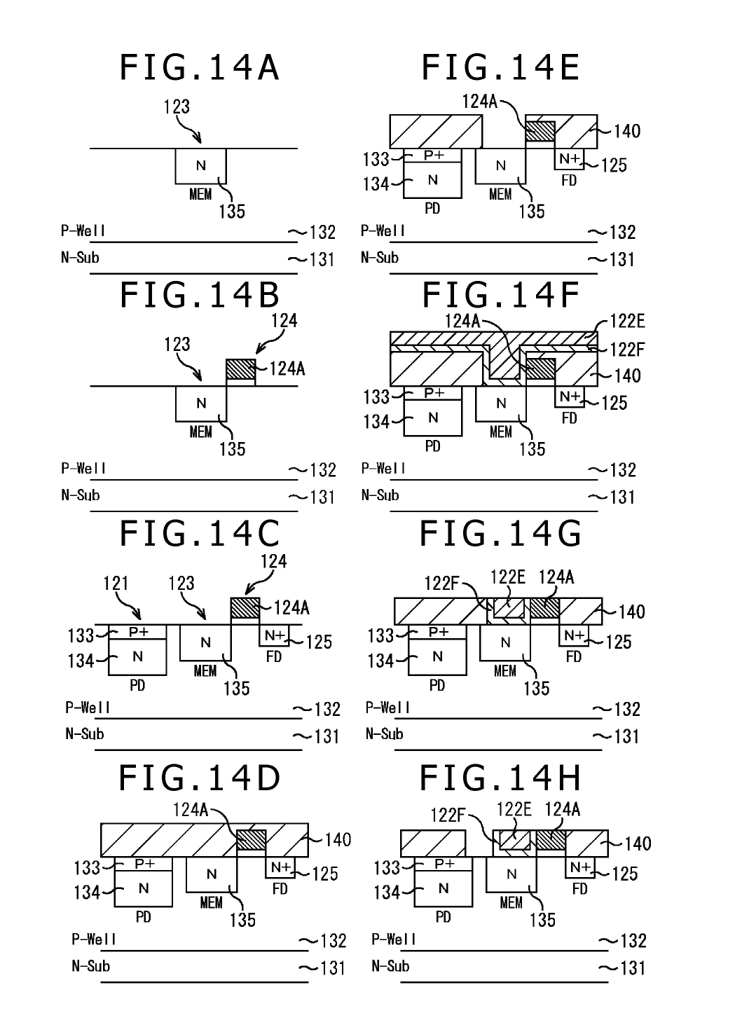

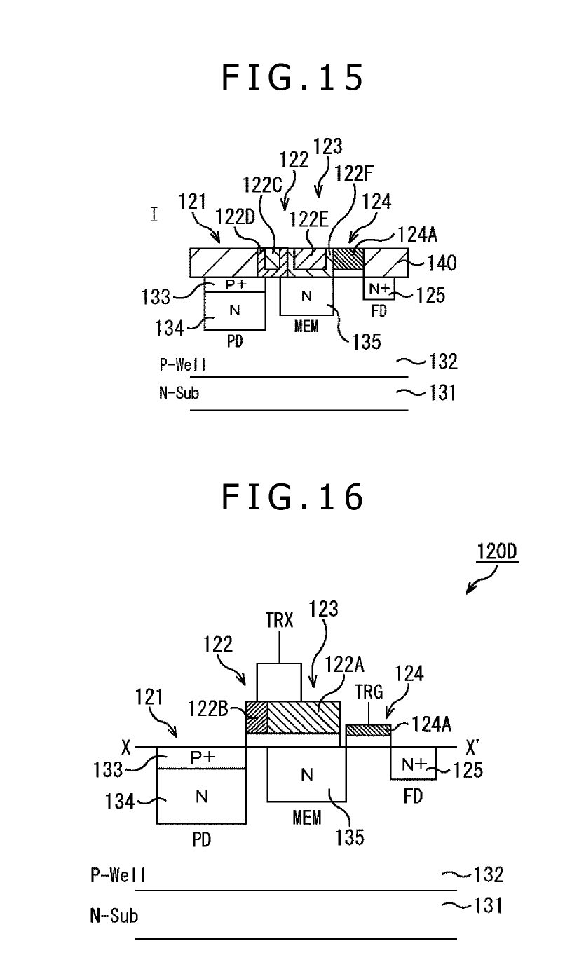

Processes for manufacturing the unit pixel 120C of FIG. 13 will next be described with reference to FIGS. 14A to 14H and FIG. 15.

First, as shown in FIG. 14A, an ion implantation process is performed to form a memory part (MEM) 123 as an N-type region in a P-type well layer 132 formed on an N-type substrate 131.

Next, as shown in FIG. 14B, a silicon oxide film is formed by a thermal oxidation process, and thereafter a Poly-Si film is formed and a patterning process is performed to form the gate electrode 124A of a second transfer gate 124. Then, as shown in FIG. 14C, an ion implantation process is performed to form a photodiode (PD) 121 and a floating diffusion region (FD) 125 in the P-type well layer 132 formed on the N-type substrate 131. The impurities are activated by a thermal process.

Thereafter, as shown in FIG. 14D, an interlayer insulating film 140 is formed on the surface side of the P-type well layer 132 after the photodiode (PD) 121, the memory part (MEM) 123, the second transfer gate 124, and the floating diffusion region (FD) 125 are formed. Then, in a photolithographic process and a dry etching process, as shown in FIG. 14E, the interlayer insulating film 140 is etched for a part in which to form a gate electrode above the memory part (MEM) 123.

Next, as shown in FIG. 14F, a gate insulating film 122F formed by a silicon oxide film or a high dielectric constant insulating film is deposited on the part processed into a predetermined shape by the etching, and a metallic gate 122E made of titanium nitride (TiN) or the like is further laminated. Then, the metallic gate 122E laminated on the gate insulating film 122F as shown in FIG. 14G is formed by performing a damascene process. The metallic gate 122E made of titanium nitride (TiN) or the like is thereby disposed above the memory part 123. Further, as shown in FIG. 14H, the interlayer insulating film 140 is etched for a part in which to form a gate electrode above a boundary part between the photodiode (PD) 121 and the memory part (MEM) 123. Then, as in FIG. 12F, a gate insulating film 122D formed by a silicon oxide film or a high dielectric constant insulating film is deposited, a metallic gate 122C made of HfSix is further laminated, and a damascene process is performed. As shown in FIG. 15, the metallic gate 122C made of HfSix or the like is thereby disposed above the part serving as the overflow path 130.

A CMOS image sensor 100 having the unit pixel 120C of FIG. 13 can be obtained by thereafter undergoing predetermined known manufacturing processes.

### 4. Fourth Embodiment

### Structure of Unit Pixel

A fourth embodiment of the present invention will next be described with reference to FIG. 16. The fourth embodiment is different from the first embodiment in that P-type Poly-Si and N-type Poly-Si are formed in ion implantation.

FIG. 16 is a diagram showing a constitution of a unit pixel 120D. Incidentally, in FIG. 16, parts corresponding to those of FIG. 8 are identified by the same reference symbols, and description thereof will be omitted as appropriate.

In the unit pixel 120D, a gate electrode 122A made of P-type Poly-Si (polycrystalline silicon) is formed above a memory part 123. In addition, a gate electrode 122B made of N-type Poly-Si (polycrystalline silicon) is formed above a part serving as an overflow path 130 formed in a boundary part between a photodiode (PD) 121 and the memory part (MEM) 123.

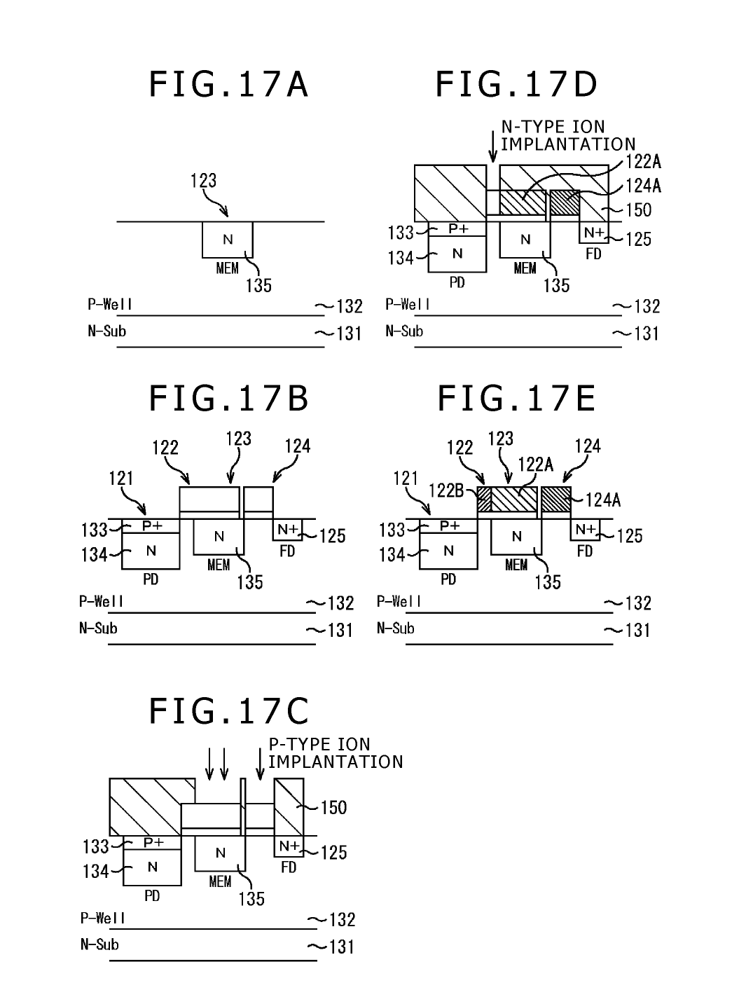

Specifically, in the unit pixel 120D, a first transfer gate 122 made of Poly-Si is formed above the memory part 123, and then the gate electrode 122A made of P-type Poly-Si and the gate electrode 122B made of N-type Poly-Si are formed by ion implantation. When the gate electrodes are thus formed, a P-type impurity and an N-type impurity are diffused within the first transfer gate 122 made of Poly-Si, and thus there is a transition part. However, because gate formation is completed in a single process, processes can be reduced. Incidentally, details of the process will be described in a section of processes for manufacturing the unit pixel 120D in FIGS. 17A to 17E.

In the unit pixel 120D formed as described above, when a transfer pulse TRX is applied to the gate electrode 122A and the gate electrode 122B, the potential of the part serving as the overflow path 130 is depressed because the work function of the gate electrode 122B (N-type Poly-Si) is smaller than the work function of the gate electrode 122A (P-type Poly-Si).

### [Manufacturing Processes]

Processes for manufacturing the unit pixel 120D of FIG. 16 will next be described with reference to FIGS. 17A to 17G.

First, as shown in FIG. 17A, an ion implantation process is performed to form a memory part (MEM) 123 as an N-type region in a P-type well layer 132 formed on an N-type substrate 131.

Next, as shown in FIG. 17B, a thermal oxidation process is performed to form a silicon oxide film, and thereafter a Poly-Si film is formed and a patterning process is performed to form a first transfer gate 122 and a second transfer gate 124. Further, an ion implantation process is performed to form a photodiode (PD) 121 and a floating diffusion region (FD) 125 in the P-type well layer 132 formed on the N-type substrate 131.

Thereafter, as shown in FIG. 17C, a photoresist 150 is patterned, and P-type ions (for example boron or the like) are implanted into parts that are to become the gate electrode 122A of the first transfer gate 122 and the gate electrode 124A of the second transfer gate 124. Further, as shown in FIG. 17D, a photoresist 150 is patterned, and N-type ions (for example phosphorus or the like) are implanted into a part that is to become the gate electrode 122B of the first transfer gate 122.

Finally, a thermal process is performed to activate the impurities. Consequently, as shown in FIG. 17E, the gate electrode 122A made of P-type Poly-Si is disposed above the memory part 123, and the gate electrode 122B made of N-type Poly-Si is disposed above the part serving as the overflow path 130.

A CMOS image sensor 100 having the unit pixel 120D of FIG. 16 can be obtained by thereafter undergoing predetermined known manufacturing processes.

As described above, in the fourth embodiment, the gate electrode 122A made of P-type Poly-Si and the gate electrode 122B made of N-type Poly-Si are disposed as gate electrodes with different work functions which gate electrodes are disposed above the memory part 123 and the overflow path 130. An offset between the gate electrodes depresses the potential of the P-type well layer 132 in the boundary part between the photodiode 121 and the memory part 123, and thereby forms the overflow path 130.

In addition, the manufacturing processes of the fourth embodiment are simplified because the P-type region and the N-type region in the first transfer gate 122 are only separated from each other by impurity implantation. However, because diffusion varies between the P-type region and the N-type region, and a depletion layer is formed, a characteristic of control of the potential of the overflow barrier is somewhat degraded.

### 5. Examples of Modification

The description of the second embodiment (FIG. 11) has been made supposing that of the gate electrode 122A and the gate electrode 122B, the gate electrode 122A is formed by P-type polycrystalline silicon, and that the gate electrode 122B is formed by a metal. However, the reverse is also possible, that is, the gate electrode 122A may be formed by a metal, and the gate electrode 122B may be formed by N-type polycrystalline silicon. In this case, the gate electrode 122A is for example formed by metals selected from a group including titanium (Ti), molybdenum (Mo), ruthenium (Ru), and the like, alloys containing these metals, or compounds of these metals, whose work function is close to the work function of P-type Poly-Si, as described in the third embodiment (FIG. 13).

In addition, the conduction types of the device structures in the unit pixels 120A to 120D according to the first to fourth embodiments described above are a mere example, and the N-type and the P-type may be changed to the opposite types. The conduction type of the N-type substrate 131 may also be either of the N-type and the P-type.

In addition, ions may be lightly implanted into the P-type well layer 132 in the boundary part between the photodiode (PD) 121 and the memory part (MEM) 123 to assist the gate electrodes with different work functions in depressing the potential of the P-type well layer 132.

The present invention is not limited to application to solid-state imaging devices. That is, the present invention is applicable to electronic apparatuses in general using a solid-state imaging device in an image capturing section (photoelectric converting section), which electronic apparatuses include imaging devices such as digital still cameras, video cameras and the like, portable terminal devices having an imaging function, copiers using a solid-state imaging device in an image reading section, and the like. The solid-state imaging devices may be formed as one chip, or may be in the form of a module having an imaging function in which module an imaging section and a signal processing section or an optical system are collectively packaged.

[Example of Configuration of Electronic Apparatus to which Present Invention is Applied]

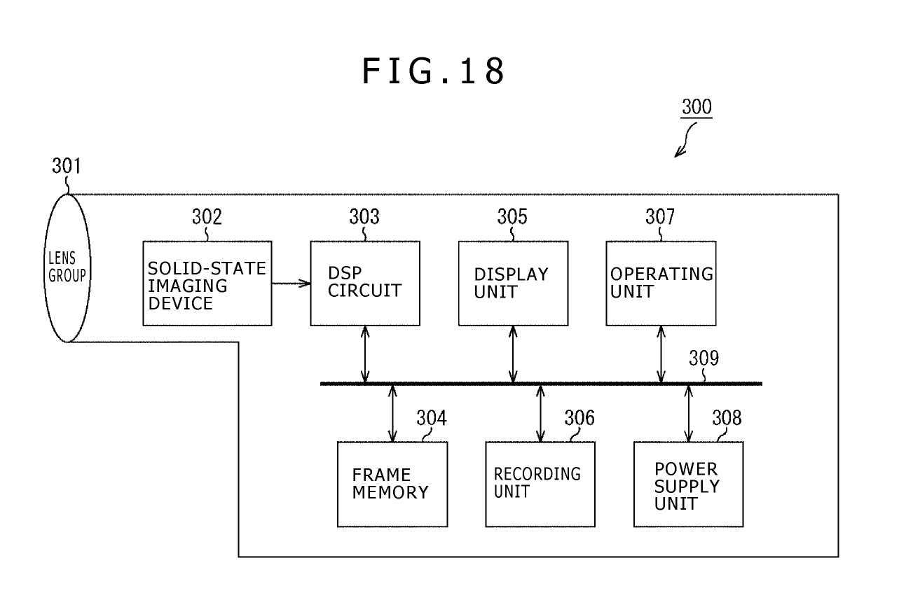

FIG. 18 is a block diagram showing an example of configuration of an imaging device as an electronic apparatus to which the present invention is applied.

The imaging device 300 of FIG. 18 includes an optical section 301 composed of a lens group and the like, a solid-state imaging device (imaging device) 302 employing each of the constitutions of the unit pixels 120 described above, and a DSP (Digital Signal Processor) circuit 303 as a camera signal processing circuit. The imaging device 300 also includes a frame memory 304, a display unit 305, a recording unit 306, an operating unit 307, and a power supply unit 308. The DSP circuit 303, the frame memory 304, the display unit 305, the recording unit 306, the operating unit 307, and the power supply unit 308 are interconnected via a bus line 309.

The optical section 301 captures incident light (image light) from a subject, and forms an image on an imaging surface of the solid-state imaging device 302. The solid-state imaging device 302 converts an amount of incident light whose image is formed on the imaging surface by the optical section 301 into an electric signal in pixel units, and outputs the electric signal as a pixel signal. The solid-state imaging devices of the CMOS image sensors 100 according to the above-described embodiments or the like, that is, a solid-state imaging device capable of achieving imaging free from distortion by global exposure can be used as the solid-state imaging device 302.

The display unit 305 is for example formed by a panel type display device such as a liquid crystal panel, an organic EL (electro luminescence) panel, or the like. The display unit 305 displays a moving image or a still image picked up by the solid-state imaging device 302. The recording unit 306 records the moving image or the still image picked up by the solid-state imaging device 302 onto a recoding medium such as a video tape, a DVD (Digital Versatile Disk), or the like.

The operating unit 307 issues an operation command for various functions of the imaging device 300 under operation by a user. The power supply unit 308 supplies various kinds of power as operating power for the DSP circuit 303, the frame memory 304, the display unit 305, the recording unit 306, and the operating unit 307 to these supply objects as appropriate.

As described above, by using the CMOS image sensors 100 according to the above-described embodiments as the solid-state imaging device 302, noise caused by variations in threshold value of pixel transistors can be reduced, and therefore a high S/N can be ensured. Thus, the image quality of picked-up images can be enhanced also in the imaging device 300 such as a video camera or a digital still camera as well as a camera module for a mobile apparatus such as a portable telephone or the like.

In addition, the foregoing embodiments have been described by taking as an example a case where the present invention is applied to a CMOS image sensor formed by arranging unit pixels sensing a signal charge corresponding to an amount of visible light as a physical quantity in the form of a matrix. However, the present invention is not limited to application to CMOS image sensors, but is applicable to solid-state imaging devices of a column system in general which devices are formed with a column processing section arranged for each pixel column of a pixel array section.

In addition, the present invention is not limited to application to solid-state imaging devices for sensing a distribution of amounts of incident visible light and picking up the distribution as an image. The present invention is applicable to solid-state imaging devices for picking up a distribution of amounts of incidence of infrared rays, X-rays, particles or the like as an image and, in a broad sense, solid-state imaging devices (physical quantity distribution sensing devices) in general including for example fingerprint detecting sensors for sensing a distribution of another physical quantity such as pressure, capacitance or the like, and picking up the distribution as an image.

It is to be noted that in the present specification, the steps described in the flowchart may of course be performed in time series in the described order, but may also be performed in parallel or in necessary timing when a call is made, for example, without being necessarily processed in time series.

Embodiments of the present invention are not limited to the above-described embodiments, but various changes can be made without departing from the spirit of the present invention.

The present application contains subject matter related to that disclosed in Japanese Priority Patent Application JP 2010-080526 filed with the Japan Patent Office on Mar. 31, 2010, the entire content of which is hereby incorporated by reference.

What is claimed is:

1. A solid-state imaging device, comprising
a plurality of unit pixels,
wherein the plurality of unit pixels include:
a photoelectric conversion element for generating a charge corresponding to an amount of incident light and internally accumulating the charge;
a first transfer gate for transferring the charge accumulated in said photoelectric conversion element;
a charge retaining region for retaining the charge transferred from said photoelectric conversion element by said first transfer gate;
a second transfer gate for transferring the charge retained in said charge retaining region; and
a floating diffusion region for retaining the charge transferred from said charge retaining region by said second transfer gate to read the charge transferred from said charge retaining region by said second transfer gate as a signal;
a boundary part between said photoelectric conversion element and said charge retaining region having a structure of an overflow path formed at a potential determining a predetermined amount of charge, the overflow path transferring a charge by which said predetermined amount of charge is exceeded as a signal charge from said photoelectric conversion element to said charge retaining region, and
said first transfer gate having two electrodes with different work functions as gate electrodes arranged above said overflow path and above said charge retaining region, respectively.

2. The solid-state imaging device according to claim 1,
wherein the work function of the electrode above said overflow path as one of said gate electrodes is smaller than the work function of the electrode above said charge retaining region as the other of said gate electrodes.

3. The solid-state imaging device according to claim 2,
wherein the electrode above said overflow path as one of said gate electrodes is N-type polycrystalline silicon, and the electrode above said charge retaining region as the other of said gate electrodes is P-type polycrystalline silicon.

4. The solid-state imaging device according to claim 3,
wherein said N-type polycrystalline silicon and said P-type polycrystalline silicon are separated from each other by an insulating layer.

5. The solid-state imaging device according to claim 3,
wherein said gate electrodes are of a polycrystalline silicon structure in an identical layer, and are separated into said N-type polycrystalline silicon and said P-type polycrystalline silicon by implantation of different impurities.

6. The solid-state imaging device according to claim 2,
wherein the electrode above said overflow path as one of said gate electrodes is an electrode formed of a metal, and the electrode above said charge retaining region as the other of said gate electrodes is P-type polycrystalline silicon.

7. The solid-state imaging device according to claim 2,
wherein the electrode above said overflow path as one of said gate electrodes is N-type polycrystalline silicon, and the electrode above said charge retaining region as the other of said gate electrodes is an electrode formed of a metal.

8. The solid-state imaging device according to claim 2,
wherein the electrode above said overflow path and the electrode above said charge retaining region as said gate electrodes are electrodes formed of different kinds of metal.

9. The solid-state imaging device according to claim 1,
wherein each electrode of said gate electrodes is connected to identical wiring.

10. A method for manufacturing a solid-state imaging device, the method comprising the steps of:
forming, in a semiconductor substrate, a charge retaining region for retaining a charge transferred from a photoelectric conversion element for generating the charge corresponding to an amount of incident light and internally accumulating the charge;
forming a first gate electrode of a first transfer gate for transferring the charge accumulated in said photoelectric conversion element, the first gate electrode being disposed above said charge retaining region, and a gate electrode of a second transfer gate for transferring the charge retained in said charge retaining region;
forming a second gate electrode with a work function different from a work function of said first gate electrode, the second gate electrode being disposed above an overflow path for transferring a charge by which a predetermined amount of charge is exceeded from said photoelectric conversion element to said charge retaining region in a boundary part between said photoelectric conversion element and said charge retaining region; and
forming said photoelectric conversion element and a floating diffusion region for retaining the charge transferred from said charge retaining region by said second transfer gate to read the charge transferred from said charge retaining region by said second transfer gate as a signal.

11. A method for manufacturing a solid-state imaging device, the method comprising the steps of:
forming, in a semiconductor substrate, a charge retaining region for retaining a charge transferred from a photoelectric conversion element for generating the charge corresponding to an amount of incident light and internally accumulating the charge;
forming a first transfer gate for transferring the charge accumulated in said photoelectric conversion element and a second transfer gate for transferring the charge retained in said charge retaining region;
forming said photoelectric conversion element and a floating diffusion region for retaining the charge transferred from said charge retaining region by said second transfer gate to read the charge transferred from said charge retaining region by said second transfer gate as a signal; and
implanting ions into parts to become a first gate electrode of said first transfer gate, the first gate electrode being disposed above said charge retaining region, a second gate electrode of said first transfer gate, the second gate electrode having a work function different from a work function of said first gate electrode, and the second gate electrode being disposed above an overflow path for transferring a charge by which a predetermined amount of charge is exceeded from said photoelectric conversion element to said charge retaining region in a boundary part between said photoelectric conversion element and said charge retaining region, and a gate electrode of said second transfer gate.

12. The method for manufacturing the solid-state imaging device according to claim 11,
wherein the step of implanting the ions implants P-type ions into the parts to become said first gate electrode of said first transfer gate and said gate electrode of said second transfer gate after performing patterning by a photoresist, and further implants N-type ions into said second gate electrode of said first transfer gate after performing patterning by a photoresist.

13. A method for manufacturing a solid-state imaging device, the method comprising the steps of:
forming, in a semiconductor substrate, a charge retaining region for retaining a charge transferred from a photoelectric conversion element for generating the charge corresponding to an amount of incident light and internally accumulating the charge;
forming a first gate electrode of a first transfer gate for transferring the charge accumulated in said photoelectric conversion element, the first gate electrode being disposed above said charge retaining region, and a gate electrode of a second transfer gate for transferring the charge retained in said charge retaining region;
forming said photoelectric conversion element and a floating diffusion region for retaining the charge transferred from said charge retaining region by said second transfer gate to read the charge transferred from said charge retaining region by said second transfer gate as a signal;
forming a predetermined interlayer insulating film on said semiconductor substrate;
etching said interlayer insulating film so that a second gate electrode with a work function different from a work function of said first gate electrode can be disposed, the second gate electrode being to be disposed above an overflow path for transferring a charge by which a predetermined amount of charge is exceeded from said photoelectric conversion element to said charge retaining region in a boundary part between said photoelectric conversion element and said charge retaining region; and
forming said second gate electrode by depositing a predetermined insulating film and laminating a predetermined metal in a part formed by etching said interlayer insulating film, the part formed by etching said interlayer insulating film being in a shape in which said second gate electrode can be disposed, and then removing an unnecessary metallic layer.

14. A method for manufacturing a solid-state imaging device, the method comprising the steps of:
forming, in a semiconductor substrate, a charge retaining region for retaining a charge transferred from a photoelectric conversion element for generating the charge corresponding to an amount of incident light and internally accumulating the charge;
forming a gate electrode of a second transfer gate for transferring the charge retained in said charge retaining region;
forming said photoelectric conversion element and a floating diffusion region for retaining the charge transferred from said charge retaining region by said second transfer gate to read the charge transferred from said charge retaining region by said second transfer gate as a signal;
forming a predetermined interlayer insulating film on said semiconductor substrate;
etching said interlayer insulating film so that a first gate electrode of a first transfer gate for transferring the charge accumulated in said photoelectric conversion element, the first gate electrode being to be disposed above said charge retaining region, can be disposed;
forming said first gate electrode by depositing a predetermined insulating film and laminating a first metal in a part formed by etching said interlayer insulating film, the part formed by etching said interlayer insulating film being in a shape in which said first gate electrode can be disposed, and then removing an unnecessary metallic layer;
etching said interlayer insulating film so that a second gate electrode with a work function different from a work function of said first gate electrode can be disposed, the second gate electrode being to be disposed above an overflow path for transferring a charge by which a predetermined amount of charge is exceeded from said photoelectric conversion element to said charge retaining region in a boundary part between said photoelectric conversion element and said charge retaining region; and
forming said second gate electrode by depositing a predetermined insulating film and laminating a second metal different from said first metal in a part formed by etching said interlayer insulating film, the part formed by etching said interlayer insulating film being in a shape in which said second gate electrode can be disposed, and then removing an unnecessary metallic layer.

15. An electronic apparatus mounted on a solid-state imaging device,
wherein the solid-state imaging device includes
a plurality of unit pixels, the plurality of unit pixels including:
a photoelectric conversion element for generating a charge corresponding to an amount of incident light and internally accumulating the charge;
a first transfer gate for transferring the charge accumulated in said photoelectric conversion element;
a charge retaining region for retaining the charge transferred from said photoelectric conversion element by said first transfer gate;
a second transfer gate for transferring the charge retained in said charge retaining region; and
a floating diffusion region for retaining the charge transferred from said charge retaining region by said second transfer gate to read the charge transferred from said charge retaining region by said second transfer gate as a signal;
a boundary part between said photoelectric conversion element and said charge retaining region having a structure of an overflow path formed at a potential determining a predetermined amount of charge, the overflow path transferring a charge by which said predetermined amount of charge is exceeded as a signal charge from said photoelectric conversion element to said charge retaining region, and
said first transfer gate having two electrodes with different work functions as gate electrodes arranged above said overflow path and above said charge retaining region, respectively.
